(19) United States
(12) Patent Application Publication
(10) Pub. No.: US 2025/0364065 A1
(43) Pub. Date: Nov. 27, 2025

(54) TRANSIENT THRESHOLD VOLTAGE SCAN

(71) Applicant: Micron Technology, Inc., Boise, ID (US)

(72) Inventors: Daniel Danching Zhang, Milpitas, CA (US); Michael William Winterfeld, Firestone, CO (US); Paul Roger Stonelake, Kihei, HI (US); Dheeraj Srinivasan, San Jose, CA (US); Ankit Vashi, San Jose, CA (US); Sead Zildzic, Folsom, CA (US)

(21) Appl. No.: 19/213,543

(22) Filed: May 20, 2025

Related U.S. Application Data
(60) Provisional application No. 63/651,702, filed on May 24, 2024.

(51) Int. Cl. G11C 16/34; G11C 16/20; G11C 16/26; G11C 16/32

(52) U.S. Cl. CPC G11C 16/3495; G11C 16/20; G11C 16/26; G11C 16/32

(57) ABSTRACT

Methods, systems, and devices for transient threshold voltage scan are described. For example, a memory system may set or maintain one or more memory blocks in a transient voltage threshold (VT) state by periodically applying a read voltage to sets of one or more memory blocks in the memory system. The memory system may apply the read voltage to a set of memory blocks simultaneously using a ganged reset read (GRR). In some examples, the memory system may reset a block range (e.g., across all memory blocks of the memory system) by periodically applying the read voltage to sets of memory blocks over time to maintain the memory blocks in the transient VT state and to reduce a bit error rate associated with a stable VT state to which the memory blocks may transition if they are not reset within a threshold duration.

### CROSS REFERENCE

The present application for patent claims priority to U.S. Patent Application No. 63/651,702 by Zhang et al., entitled “TRANSIENT THRESHOLD VOLTAGE SCAN,” filed May 24, 2024, which is assigned to the assignee hereof, and which is expressly incorporated by reference in its entirety herein.

### TECHNICAL FIELD

The following relates to one or more systems for memory, including transient threshold voltage scan.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports transient threshold voltage scan in accordance with examples as disclosed herein.

FIG. 2 shows an example of a voltage distribution that supports transient threshold voltage scan in accordance with examples as disclosed herein.

FIG. 3 shows an example of a process flow that supports transient threshold voltage scan in accordance with examples as disclosed herein.

FIG. 4 shows a block diagram of a memory system that supports transient threshold voltage scan in accordance with examples as disclosed herein.

FIGS. 5 and 6 show flowcharts illustrating methods that support transient threshold voltage scan in accordance with examples as disclosed herein.

### DETAILED DESCRIPTION

Memory cells may be associated with a voltage threshold (VT) that determines a logic state of a respective memory cell. In some memory systems, a memory cell (e.g., a not-AND (NAND) flash cell or some other type of memory cell) that has not been accessed for some time (e.g., a threshold duration) may experience degradation, which may correspond to a shift from a transient VT state to a stable VT state (e.g., the memory cell may experience a “first read” phenomenon). The stable VT state may correspond to a first voltage distribution and the transient VT state may correspond to a second voltage distribution, where the first voltage distribution may be associated with a higher bit error rate (BER) compared to second voltage distribution. The second voltage distribution may be a default (e.g., intended, expected) voltage distribution for the memory cell. The stable VT state may thereby correspond to a shifted VT state in which access operations may be unsuccessful or otherwise inaccurate due to changes of the VT over time due to degradation, whereas the transient VT state may be associated with a programmable state, in which access operations may be performed reliably. For example, various logical states may be programmed to or read from the memory cell according to the second voltage distribution. The first voltage distribution, however, may correspond to a migration of the default distribution over time due to the memory cell degradation. The stable VT state may cause the memory cell to exhibit a BER during an initial read of the memory cell (e.g., a read after the threshold duration) at least because one or more voltages may not correspond to expected logical states of the memory cell based on the shifted voltage distribution, which may increase errors when accessing the memory cell. The increased BER may lead to more instances of read error handling for the memory system, potentially affecting response latency and overall system performance, among other examples.

Some memory systems may access the memory cells periodically as part of a background scan. Additionally, or alternatively, some memory systems may perform a dummy read prior to performing the background scan. However, the threshold duration for a memory cell to shift to the stable VT state may be shorter than an interval between the dummy reads or background scans, and the memory system may not know which memory cells a host will request access to prior to receiving the access command. Accordingly, it may be beneficial to proactively set the one or more memory cells to the transient VT state to reduce BER and support improved access operations.

The techniques described herein may enable a memory system to proactively set one or more memory blocks to the transient VT state (e.g., a programmable VT state) by periodically applying a read voltage to the one or more memory blocks (e.g., within the threshold duration, before or relatively soon after the memory blocks enter the stable VT state). After the memory system is powered on and initialized, the memory system may apply the read voltages to the one or more memory blocks periodically. In some examples, the memory system may apply the read voltage to multiple memory blocks simultaneously using a ganged reset read (GRR). Additionally, or alternatively, the memory system may apply the read voltage one memory block at a time. In some examples, the memory system may periodically apply the read voltage across a block range (e.g., across all memory blocks of the memory system) to maintain the memory blocks in the transient VT state and to mitigate the increased BER associated with the stable VT state.

In some examples, periodically applying the read voltage to the one or more memory blocks may reduce a latency associated with the stable VT state. For example, relatively large capacity memory systems with relatively slow random read workloads, among other types of systems, may benefit from reduced latency if the memory blocks are maintained in a transient VT state. Additionally, or alternatively, applying the read voltage to multiple memory blocks simultaneously may reduce a quantity of background scans (e.g., multiple blocks may be accessed per plane compared to memory systems that access one block per plane).

In addition to applicability in memory systems as described herein, techniques for a transient threshold voltage scan may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing BER caused by reading from memory blocks with a stable VT, which may decrease latency times (e.g., latency associated with performing error handling), improve memory reliability, or otherwise improve user experience, among other benefits.

Features of the disclosure are illustrated and described in the context of systems, devices, and circuits. Features of the disclosure are further illustrated and described in the context of voltage distributions, process flows, and flowcharts.

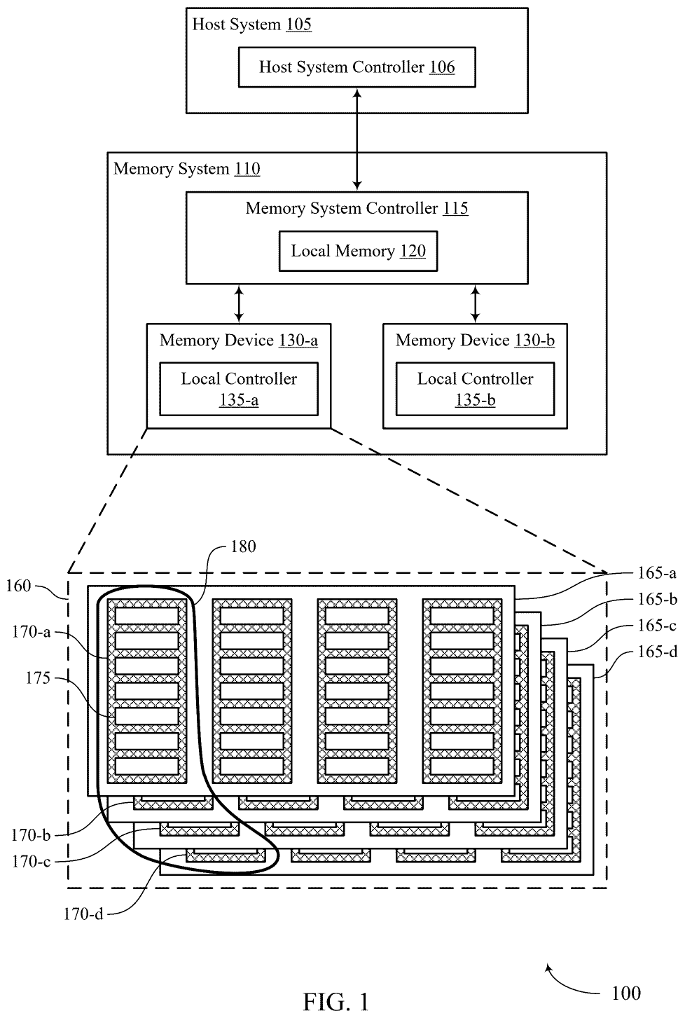

FIG. 1 shows an example of a system 100 that supports transient threshold voltage scan in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

Memory cells may be associated with a VT that determines a logic state of a respective memory cell. In some memory systems 110, a memory cell (e.g., NAND flash cell, or some other type of cell) that has not been accessed for a threshold duration may shift from a transient VT state to a stable VT state (e.g., experience a “first read” phenomenon). The stable VT state may correspond to a first voltage distribution and the transient VT state may correspond to a second voltage distribution, where the first voltage distribution is associated with a BER compared to second voltage distribution. For example, the stable VT state may cause the memory cell to exhibit a BER during an initial read of the memory cell (e.g., a read after the threshold duration). The increased BER may lead to more instances of read error handling for the memory system, potentially affecting response latency and overall system performance.

Some memory systems 110 may access the memory cells periodically as part of a background scan. Additionally, or alternatively, some memory systems 110 may perform a dummy read prior to performing the background scan. However, the threshold duration for a memory cell to shift to the stable VT state may be shorter than an interval between the dummy reads or background scans, and a memory system 110 may not know which memory cells a host system 105 may request access to prior to receiving the access command. Accordingly, it may be desirable to set the one or more memory cells to the transient VT state to reduce the increased BER associated with the stable VT state.

The techniques described herein may enable one or more memory blocks 170 to be set to the transient VT state by periodically applying a read voltage to the one or more memory blocks 170 within the threshold duration. In some examples, the memory system 110 may apply the read voltage to multiple memory blocks 170 simultaneously using a GRR. For example, a GRR may refer to the memory system 110 reading multiple memory blocks 170 simultaneously (e.g., the memory system 110 may perform multiple reset reads on multiple memory blocks 170 in a single operation).

Additionally, or alternatively, the memory system 110 may apply the read voltage one memory block 170 at a time. For example, based powering on and initializing the memory system 110, the memory system 110 may apply the read voltages to the one or more memory blocks 170. In some examples, the memory system may periodically apply the read voltage across a block range (e.g., across all memory blocks 170 of the memory system 110) to maintain the memory blocks 170 in the transient VT state and to mitigate the increased BER associated with the stable VT state.

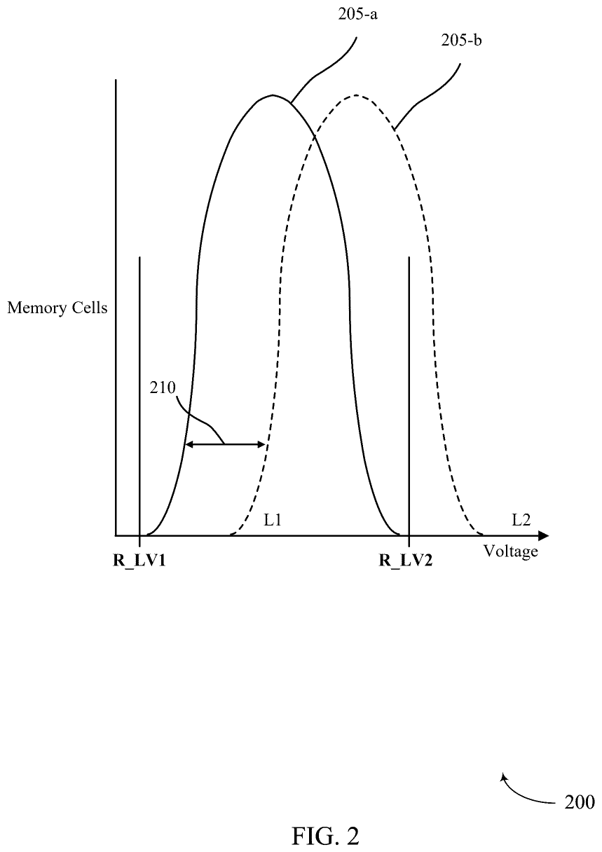

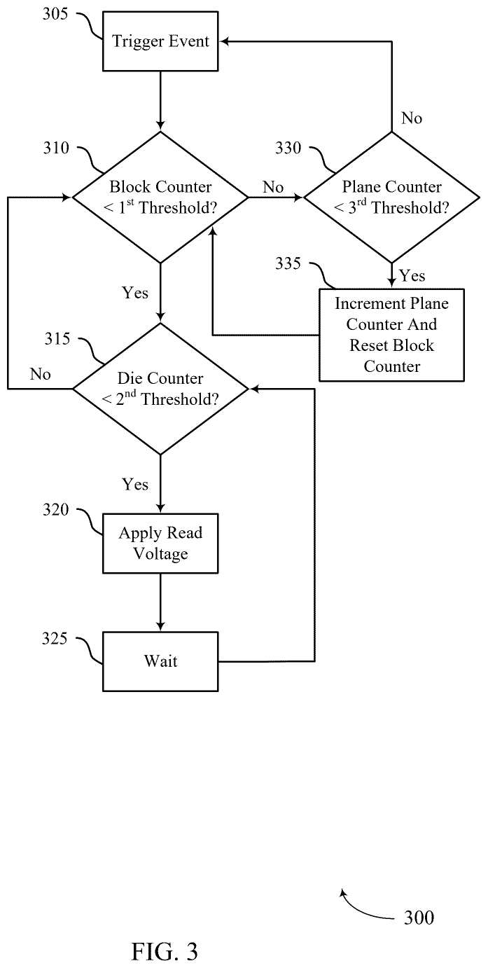

For example, the memory system 110 may apply the read voltage to a first quantity of memory blocks 170 in a plane 165 of a first die 160. After (e.g., in response to, based on) applying the read voltage to the first quantity of memory blocks 170, the memory system 110 may apply the read voltage to a second quantity of memory blocks 170 in a plane 165 of a second die 160. The memory system 110 may iteratively apply the read voltage to a threshold quantity of memory blocks 170 (e.g., the total quantity of memory blocks per plane 165, such as four memory blocks) in a threshold quantity of dies 160 (e.g., the total quantity of dies 160 in the memory system 110), or according to some other pattern, to ensure that the memory blocks 170 are all periodically refreshed and maintained in the transient VT state, as described in further detail elsewhere herein, including with reference to FIGS. 2 and 3.

FIG. 2 shows an example of a voltage diagram 200 that supports transient threshold voltage scan in accordance with examples as disclosed herein. For example, the voltage diagram 200 may include a first voltage distribution 205-a and a second voltage distribution 205-b. The voltage diagram 200 may be implemented by aspects of the system 100 as described with reference to FIG. 1. For example, the voltage distributions 205 may correspond to a logic level L for one or more memory cells associated with one or more blocks 170 and planes 165, as described with reference to FIG. 1. Each logic level L may further be defined to be above an associated read level R_LV, where read levels R_LV1 and R_LV2 may correspond to logic levels L1 and L2, respectively. In some examples, the read levels R_LV may represent threshold voltages defining each level L. The voltage distributions 205 may increase vertically in the diagram to illustrate an increased quantity of memory cells corresponding to a respective voltage (e.g., for a random set of data) and may correspond to a higher likelihood of memory cells at each voltage. Although two voltage distributions 205 for logic levels are illustrated in FIG. 2, it may be understood that the techniques described herein may apply to any quantity of voltage distributions 205 and logic levels (e.g., four or eight different logic levels).

In some examples, the first voltage distribution 205-a may be a transient VT distribution. That is, the first voltage distribution 205-a may represent an example distribution of voltages. A transient VT may be associated with a predictable (e.g., expected, configured) voltage level (e.g., L1) for a given logic state. For example, a memory system (e.g., the memory system 110) may read or write data according to the first voltage distribution 205-a. Voltages above a transient VT, such as R_LV1, within the first voltage distribution 205-a may correspond to a first logic value of a memory cell (e.g., ‘10’ or ‘11’), and voltages below R_LV2 may correspond to a second logic value of a memory cell (e.g., ‘00’ or ‘01’). In some examples, the first voltage distribution 205-a may shift (e.g., drift or migrate) over time by a delta 210 due to, for example, degradation of the memory system, among other examples. The delta 210 may be unknown to the memory system (e.g., the shifted distance may be relatively random or unpredictable). In some examples, the second voltage distribution 205-b may correspond to a shifted voltage distribution.

The second voltage distribution 205-b may be a stable VT distribution. The first voltage distribution 205-a may become the second voltage distribution 205-b based on the delta 210 increasing over time (e.g., after a threshold duration). For example, the memory system may not perform an access operation (e.g., read, write, or refresh) on the one or more memory cells corresponding to first voltage distribution 205-a for the threshold duration (e.g., the one or more cells may not be accessed for some time). Based on the memory system not accessing the one or more memory cells for the threshold duration, the first voltage distribution 205-a may drift by the delta 210 to the second voltage distribution 205-b (e.g., the memory cells shift from a transient VT state to a stable VT state).

In some examples, the second voltage distribution 205-b may increase a BER of the one or memory cells based on being shifted the delta 210 from the first voltage distribution 205-a. For example, a voltage for a memory cell that was within L1 may now shift beyond R_LV2 into L2, which may correspond to a different logic value than voltage level L1. That is, the shifted voltage may change the associated logic value of the memory cell. For example, a memory cell that was previously associated with a logic ‘00’ within the first voltage distribution 205-a may now be read as a logic ‘01’ within the second voltage distribution 205-b. In some examples, the second voltage distribution 205-b may overlap different voltage levels for logic states, which may increase error and uncertainty when reading the one or more memory cells. For example, the memory system may not accurately obtain a logic state for memory cells shifted near the R_LV2 threshold (e.g., the memory system may obtain a first logic value corresponding to L1 in a first read and obtain a second logic value corresponding to L2 in a second read).

Applying a read voltage to the one or more cells associated with the second voltage distribution 205-b may shift the second voltage distribution 205-b back by the delta 210 (e.g., applying a read may correct for the delta 210). For example, the read voltage may change the state of the one or more memory cells from the stable VT state corresponding to the second voltage distribution 205-b to the transient VT state corresponding to the first voltage distribution 205-a.

Techniques described herein may support periodically applying a read voltage to sets of one or more memory blocks (e.g., via a GRR) to transition the one or more memory blocks to the first voltage distribution 205-a. As described further with reference to FIG. 3, a memory system may perform a series of GRRs on multiple memory blocks to set the blocks of memory cells to the transient VT state associated with the first voltage distribution 205-a. Additionally, or alternatively, the memory system may perform a series of SLC reads on the quantity of blocks. Performing the GRR or series of SLC reads to set the state of the memory blocks to the transient VT may decrease a BER and an error handling latency associated with the second voltage distribution 205-b.

FIG. 3 shows an example of a process flow 300 that supports transient threshold voltage scan in accordance with examples as disclosed herein. The process flow 300 may be implemented by aspects of the system 100 as described with reference to FIG. 1. For example, the process flow 300 may be implemented by a memory system, which may be an example of the memory system 110. The process flow 300 may be an example of a process flow for performing a periodic scan (e.g., transient VT scan) as described herein. The memory system may perform the scan autonomously (e.g., without receiving a command from a host system) via a scan handler (e.g., a memory system controller 115), or some other component or electronic device.

In the following description of the process flow 300, the operations may be performed in a different order than the order shown, or other operations may be added or removed from the process flow 300. For example, some operations may also be left out of the process flow 300, may be performed in different orders or at different times, or other operations may be added to the process flow 300. Although a memory system (e.g., the memory system 110) may perform the operations of the process flow 300, some aspects of some operations may also be performed by one or more other memory systems, memory devices, host devices, controllers or other electronic devices (e.g., as described herein with respect to FIG. 1).

At 305, the memory system may detect a trigger event to apply a read voltage to one or more memory blocks. For example, the trigger event may correspond to a transition from a first power state of the memory system to a second power state that is associated with a greater power consumption than the first power state (e.g., the memory system may apply the read voltage based on a boot-up or initialization of the memory system). In some examples, the trigger event may correspond to the memory system determining that a time period satisfies a threshold duration. For example, the memory system may apply the read voltage based on a threshold duration of time after a previously applied read voltage (e.g., according to a configured scan periodicity or some other time period). Additionally, or alternatively, the trigger event may correspond to a temperature of the memory system exceeding a threshold temperature. For example, a temperature exceeding the threshold temperature may correspond to an increased likelihood that a VT state of the memory blocks will shift to the stable VT state, such that the temperature exceeding the threshold may trigger a background scan and refresh. As discussed herein, one or more memory blocks may be in a stable VT state if the one or more memory blocks (e.g., a set of memory blocks) include at least one memory cell that is in the stable VT state, while one or more other memory cells of the one or more memory blocks may be in the stable VT state, a transient VT state, or some other state.

At 310, the memory system may determine whether a block counter value is less than a first threshold. The block counter value may correspond to a quantity of memory blocks that the memory system has previously applied the read voltage to since the trigger event at 305. For example, the block counter value may correspond to a quantity of memory blocks with a transient VT state. In a first iteration after the trigger event, the block counter value may be zero (e.g., because the memory system may not have applied any read voltages yet). For subsequent iterations of the process flow 300, the memory system may update the block counter value. For example, after applying the read voltage to a first quantity of memory blocks in a first iteration and a second quantity of memory blocks in a second iteration, the block counter value may equal the sum of the first quantity of memory blocks and the second quantity of memory blocks.

The first threshold may be based on a reset sequence of the memory system (e.g., a scan sequence). In some examples, the first threshold may be a total quantity of memory blocks in a respective plane of the memory system. In other examples, the first threshold may be a portion of the total quantity of memory blocks in a respective plane of the memory system. For example, the first threshold may correspond to a quantity of memory blocks that the memory system may refresh at a same time (e.g., simultaneously, within at least some time period) as part of a GRR.

If the block counter value is less than the first threshold, the memory system may continue to 315. For example, the memory system may continue based on the quantity of memory blocks to which the read voltage has been applied being less than the total quantity of memory blocks of a plane (e.g., not all memory blocks are in the transient VT state). If the block counter value is greater than or equal to the first threshold, the memory system may continue to 330.

At 330, the memory system may determine whether a plane counter value has reached a third threshold. For example, the memory system may maintain a plane counter to track how many planes within the memory system have been refreshed. Once the block counter value exceeds (e.g., is greater than or equal to) the first threshold (e.g., at 310), the memory system may compare a value of the plane counter with the third threshold at 330. If the plane counter is less than the third threshold, the memory system may continue to 335. At 335, the memory system may increment the plane counter value (e.g., by one) and may reset the block counter value. The memory system may then return to 310 to continue the cycle of block and die iterations.

If the plane counter value is greater than or equal to the threshold (e.g., all of the planes have been refreshed), the memory system may return to 305. For example, the memory system may have applied the read voltage to the all of the memory blocks in all planes and across all dies. In such examples, the memory system may not continue the process to 315 or apply a read voltage until detecting another trigger event at 305.

In some examples, at 315, the memory system may determine whether a die counter value is less than a second threshold. The die counter value may correspond to a quantity of memory dies that the system has previously applied the read voltage to since the trigger event at 305. In a first iteration after the trigger event, the die counter value may be zero. For subsequent iterations of the process flow 300, the memory system may update the die counter value. For example, after applying the read voltage to a first quantity of memory blocks in a first die in a first iteration, and a first quantity of memory blocks in a second die in a second iteration, the die counter value may be two. The second threshold may be based on a reset sequence of the memory system. In some examples, the second threshold may be a total quantity of memory dies in the memory system. In other examples, the second threshold may be a portion of the total quantity of memory dies in the memory system. If the die counter value is less than the second threshold, the memory system may continue the process to 320. For example, the memory system may continue to 320 based on applying the read voltage to a quantity of memory dies less than the second threshold (e.g., not all memory dies are in the transient VT state).

If the die counter value is greater than or equal to the second threshold, the memory system may increment the block counter and may return to 310. That is, the memory system may have applied the read voltage to a first set of memory blocks for the second threshold quantity of memory dies. For example, the memory system may have applied the read voltage to the first threshold quantity of memory blocks (e.g., the first set of memory blocks) in a first plane of each memory die of the second threshold quantity of memory dies. The memory system may increment the block counter value based on a quantity of memory blocks that the read voltage has been applied to (e.g., if, in an iteration after the first iteration, a GRR has applied the read voltage to three memory blocks simultaneously on each memory die, the block counter value is incremented by three). The memory system may move to 310 to determine whether there are remaining blocks in the first plane to be refreshed or whether to continue to a subsequent plane in the memory system. For example, the memory system may iteratively reset all memory blocks in a plane (e.g., the first threshold) of each memory die (e.g., the second threshold) before transitioning to iteratively reset all memory blocks in one or more other planes of each memory die.

Based on determining to continue the process to 320, the memory system may apply the read voltage to one or more memory blocks of a respective die associated with a current value of the die counter. For example, the memory system, at a first time, may apply the read voltage to the first set of memory blocks in a first plane of a first memory die. The memory system may increment the die counter after applying the read voltage to the first set of memory blocks in the first plane of the first memory die.

The memory system may apply, at a second time based on one or more reset conditions, the read voltage to the second set of memory of memory blocks in a first plane of a second memory die. In some examples, the first time and the second time may correspond to a first and second iteration through the process flow 300, where the first threshold, the second threshold, and the one or more reset conditions are satisfied for each iteration. Third and fourth iterations of the process flow 300 may correspond to applying the read voltage to a third set of memory blocks (e.g., within a second plane of the first memory die) at a third time and applying the read voltage to a fourth set of memory blocks (e.g., within the second plane of the second memory die) at a fourth time.

Additionally, or alternatively, in some examples, the first set of memory blocks may be in all planes of the first memory die, and the memory system may increment the die counter after applying the read voltage to the first set of memory blocks in the first memory die, and the memory system may subsequently apply, at a second time based on one or more reset conditions, the read voltage to the second set of memory blocks, which may span all planes in a second memory die, where the first time and the second time may correspond to first and second iterations through the process flow 300. Third and fourth iterations of the process flow 300 may correspond to applying the read voltage to a third set of memory blocks within all planes of a third memory die at a third time and applying the read voltage to a fourth set of memory blocks within all planes of a fourth memory die at a fourth time.

In some examples, the memory system may apply the read voltage to multiple memory blocks simultaneously (e.g., via a GRR). In other examples, the memory system may apply the read voltage to one memory block at a time (e.g., the read voltage may be applied to one memory block per iteration of the process flow 300). Based on the GRR, the memory system may apply the read voltage to multiple memory blocks (e.g., four blocks per plane per die for each GRR operation) regardless of one or more conditions, such as: a block type of the multiple memory blocks, the multiple memory blocks including one or more bad blocks (e.g., blocks associated with an error), a quantity of data written to each of the multiple memory blocks, or whether an iterator associated with applying the read voltage will go outside a threshold range. Applying the read voltage to multiple memory blocks simultaneously (e.g., via the GRR) regardless of the one or more conditions may simplify operations at the scan handler compared to memory systems that do not implement the techniques described herein.

The memory system may update the die counter value based on applying the read voltage. The memory system may increment the die counter value based on applying the read voltage to one or more memory blocks in a die before returning to check the die counter relative to the threshold.

In some examples, the memory system may apply the read voltage according to a reset sequence and the one or more reset conditions. For example, the reset sequence may determine the first threshold and the second threshold. In some examples, the reset sequence may set the first threshold to be a total quantity of memory blocks in a plane and the second threshold to be a total quantity of memory dies in the memory system. Additionally, or alternatively, the reset sequence may set the first threshold to a portion of the total quantity of memory blocks in a plane and the second threshold to a portion of the total quantity of memory dies in the memory system. For example, the memory system may apply the read voltage to the memory blocks non-contiguously (e.g., based on a partition of data in the memory system).

Based on applying the read voltage, the memory system may continue to 325 to a wait duration prior to moving to 315 to determine whether to apply the read voltage to one or more memory blocks in the first plane of another memory die. The memory system may not continue the process flow 300 during the wait duration. That is, the memory system may not perform refresh operations during the wait duration, but the memory system may perform or continue other operations during the wait duration. In some examples, the wait duration may be the threshold duration, and the one or more reset conditions may include the threshold duration.

The threshold duration may be associated with a VT state of the one or more memory blocks. For example, the threshold duration may be set to spread the read voltages over time to maintain the one or more memory blocks in the transient VT state (e.g., the read voltage is spread out such that one or more memory blocks do not shift to the stable VT state during the scan). In some examples, the memory system may determine that a time period (e.g., the wait duration) between an applied read voltage (e.g., a read voltage applied at the first time) and applying another read voltage (e.g., at the second time) satisfies the threshold duration. Based on the one or more reset conditions being satisfied, the memory system may continue to 315 (e.g., to iteratively apply the read voltage to one or more memory blocks of one or more memory dies until the blocks have been refreshed across all of the memory dies). The memory system may thereby iterate over all blocks of memory cells by applying the read voltage to each block in a given plane across each memory die, then applying the read voltage to each block in a subsequent plane across the memory dies, and so on, until all of the memory blocks have been refreshed.

It is to be understood that the wait duration may be applied at 325, at another point during the process flow 300, or both. For example, the memory system may additionally, or alternatively, pause the reset operations between each plane refresh being complete, or at some other time to spread out the refresh operations over time and support other ongoing access operations.

In some examples, the memory system may receive an access command to access one or more memory cells within the one or more memory blocks (e.g., the first set of memory blocks, the second set of memory blocks, or both) after applying the read voltage to the one or more memory blocks. In such examples, the memory system may access the one or more memory cells based on the access command and the one or more memory cells being set to the transient VT state. The periodic refresh of the memory cells may improve such access operations by ensuring that the memory cells are maintained in the transient VT state over time.

Accessing the one or more memory cells based on the one or more cells being set to the transient VT state may reduce a BER of the one or more memory cells. For example, prior to applying the read voltage, one or more memory blocks of the first set of memory blocks and the second set of memory blocks may be set to a stable VT state (e.g., as described with reference to FIG. 2). The stable VT state may be associated with a voltage distribution with a higher BER than a voltage distribution associated with the transient VT state, and accessing the one or more memory cells after setting the memory cells to the trainset VT state may reduce the BER.

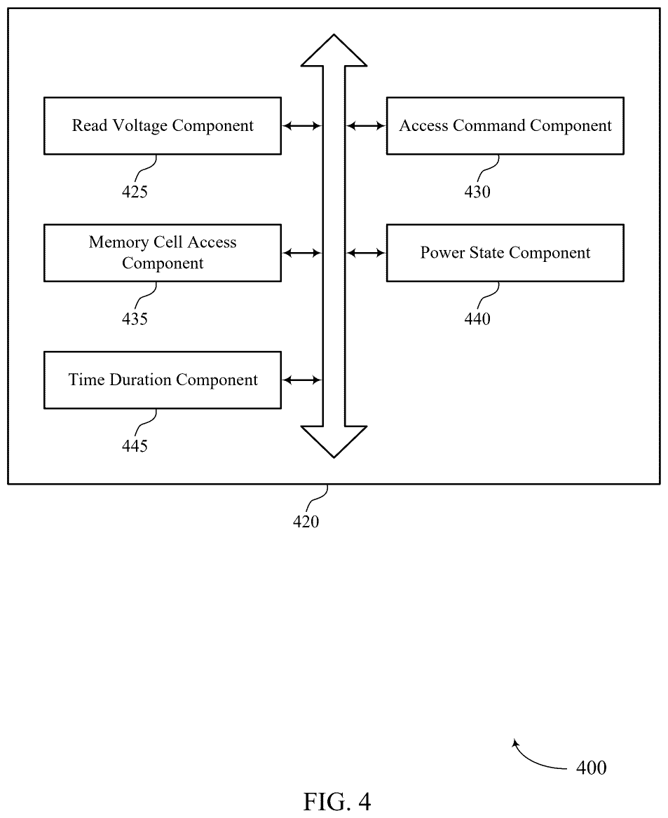

FIG. 4 shows a block diagram 400 of a memory system 420 that supports transient threshold voltage scan in accordance with examples as disclosed herein. The memory system 420 may be an example of aspects of a memory system as described with reference to FIGS. 1 through 3. The memory system 420, or various components thereof, may be an example of means for performing various aspects of transient threshold voltage scan as described herein. For example, the memory system 420 may include a read voltage component 425, an access command component 430, a memory cell access component 435, a power state component 440, a time duration component 445, or any combination thereof. Each of these components, or components of subcomponents thereof (e.g., one or more processors, one or more memories), may communicate, directly or indirectly, with one another (e.g., via one or more buses).

The memory system 420 may support a memory system in accordance with examples as disclosed herein. The read voltage component 425 may be configured as or otherwise support a means for applying, at a first time, a read voltage to a first set of memory blocks of a plurality of memory blocks, where the read voltage sets each memory block of the first set of memory blocks to a transient voltage state. In some examples, the read voltage component 425 may be configured as or otherwise support a means for applying, at a second time based at least in part on one or more reset conditions being satisfied, the read voltage to a second set of memory blocks of the plurality of memory blocks, where the read voltage sets each memory block of the second set of memory blocks to the transient voltage state. The access command component 430 may be configured as or otherwise support a means for receiving an access command to access one or more memory cells within the first set of memory blocks, the second set of memory blocks, or both after applying the read voltage to the first set of memory blocks and the second set of memory blocks. The memory cell access component 435 may be configured as or otherwise support a means for accessing the one or more memory cells based at least in part on the access command and the one or more memory cells being set to the transient voltage state.

Additionally, or alternatively, the read voltage component 425 may be configured as or otherwise support a means for applying, at a first time via a first GRR and based at least in part on one or more reset conditions being satisfied at the first time, a read voltage to a first set of memory blocks of a plurality of memory blocks, where the read voltage sets each memory block of the first set of memory blocks to a transient voltage state. In some examples, the read voltage component 425 may be configured as or otherwise support a means for applying, at a second time via a second GRR and based at least in part on the one or more reset conditions being satisfied at the second time, the read voltage to the first set of memory blocks, where the one or more reset conditions being satisfied at the second time is based at least in part on at least one memory block of the first set of memory blocks transitioning to a stable voltage state between the first time and the second time. The access command component 430 may be configured as or otherwise support a means for receiving an access command to access one or more memory cells within the first set of memory blocks after applying the read voltage to the first set of memory blocks at the second time. The memory cell access component 435 may be configured as or otherwise support a means for accessing the one or more memory cells based at least in part on the access command and the one or more memory cells being set to the transient voltage state. In some examples, the first GRR is associated with applying the read voltage to a plurality of memory cells at a same time.

In some examples, the power state component 440 may be configured as or otherwise support a means for transitioning from a first power state to a second power state that is associated with greater power consumption than the first power state, where applying the read voltage to the first set of memory blocks is based at least in part on transitioning to the second power state.

In some examples, the time duration component 445 may be configured as or otherwise support a means for determining a time period between the first time and the second time satisfies a threshold duration, where applying the read voltage to the second set of memory blocks at the second time is based at least in part on the time period satisfying the threshold duration, and where the one or more reset conditions include the threshold duration. In some examples, the one or more reset conditions include a threshold duration associated with a voltage threshold state of the plurality of memory blocks, a temperature of the plurality of memory blocks, or any combination thereof.

In some examples, the first set of memory blocks is within a first plane of a first memory die and the second set of memory blocks is within the first plane of a second memory die. In some examples, the read voltage component 425 may be configured as or otherwise support a means for applying, at a third time based at least in part on the one or more reset conditions being satisfied at the third time, the read voltage to a third set of memory blocks of the plurality of memory blocks, the third set of memory blocks within a second plane of the first memory die. In some examples, the read voltage component 425 may be configured as or otherwise support a means for applying, at a fourth time based at least in part on the one or more reset conditions being satisfied at the fourth time, the read voltage to a fourth set of memory blocks of the plurality of memory blocks, the fourth set of memory blocks within the second plane of the second memory die.

In some examples, the read voltage is applied to the first set of memory blocks and the second set of memory blocks according to a reset sequence and the one or more reset conditions, the reset sequence associated with setting a threshold quantity of memory blocks of the plurality of memory blocks to the transient voltage state.

In some examples, the reset sequence is associated with iteratively resetting all memory blocks in a plane of each memory die of a plurality of memory dies before transitioning to iteratively resetting all memory blocks in one or more other planes of each memory die of the plurality of memory dies.

In some examples, prior to applying the read voltage, one or more memory blocks of the first set of memory blocks and the second set of memory blocks are set to a stable voltage state. In some examples, the stable voltage state is associated with a first voltage distribution and the transient voltage state associated with a second voltage distribution. In some examples, the first voltage distribution is associated with a higher bit error rate than the second voltage distribution.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

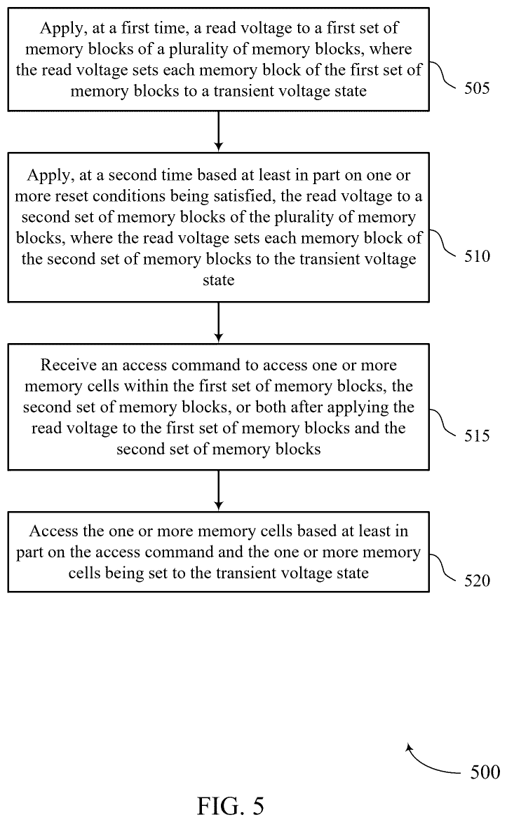

FIG. 5 shows a flowchart illustrating a method 500 that supports transient threshold voltage scan in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include applying, at a first time, a read voltage to a first set of memory blocks of a plurality of memory blocks, where the read voltage sets each memory block of the first set of memory blocks to a transient voltage state. In some examples, aspects of the operations of 505 may be performed by a read voltage component 425 as described with reference to FIG. 4.

At 510, the method may include applying, at a second time based at least in part on one or more reset conditions being satisfied, the read voltage to a second set of memory blocks of the plurality of memory blocks, where the read voltage sets each memory block of the second set of memory blocks to the transient voltage state. In some examples, aspects of the operations of 510 may be performed by a read voltage component 425 as described with reference to FIG. 4.

At 515, the method may include receiving an access command to access one or more memory cells within the first set of memory blocks, the second set of memory blocks, or both after applying the read voltage to the first set of memory blocks and the second set of memory blocks. In some examples, aspects of the operations of 515 may be performed by an access command component 430 as described with reference to FIG. 4.

At 520, the method may include accessing the one or more memory cells based at least in part on the access command and the one or more memory cells being set to the transient voltage state. In some examples, aspects of the operations of 520 may be performed by a memory cell access component 435 as described with reference to FIG. 4.

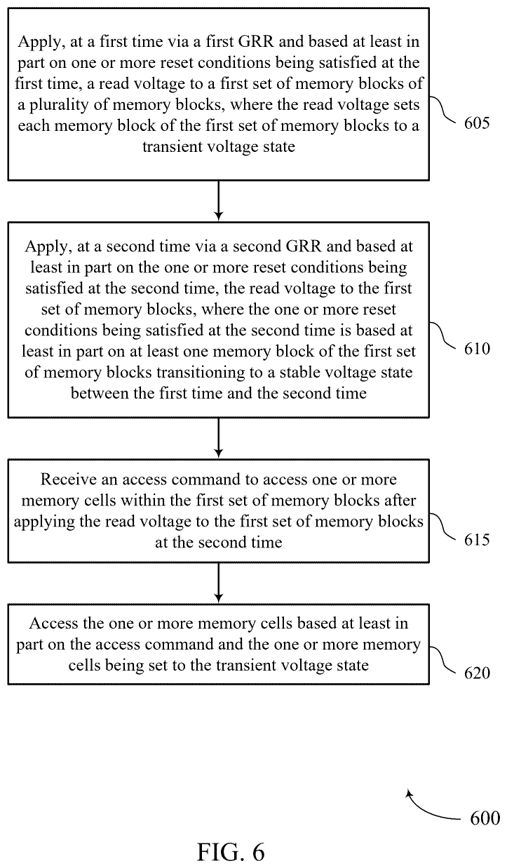

FIG. 6 shows a flowchart illustrating a method 600 that supports transient threshold voltage scan in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include applying, at a first time via a first GRR and based at least in part on one or more reset conditions being satisfied at the first time, a read voltage to a first set of memory blocks of a plurality of memory blocks, where the read voltage sets each memory block of the first set of memory blocks to a transient voltage state. In some examples, aspects of the operations of 605 may be performed by a read voltage component 425 as described with reference to FIG. 4.

At 610, the method may include applying, at a second time via a second GRR and based at least in part on the one or more reset conditions being satisfied at the second time, the read voltage to the first set of memory blocks, where the one or more reset conditions being satisfied at the second time is based at least in part on at least one memory block of the first set of memory blocks transitioning to a stable voltage state between the first time and the second time. In some examples, aspects of the operations of 610 may be performed by a read voltage component 425 as described with reference to FIG. 4.

At 615, the method may include receiving an access command to access one or more memory cells within the first set of memory blocks after applying the read voltage to the first set of memory blocks at the second time. In some examples, aspects of the operations of 615 may be performed by an access command component 430 as described with reference to FIG. 4.

At 620, the method may include accessing the one or more memory cells based at least in part on the access command and the one or more memory cells being set to the transient voltage state. In some examples, aspects of the operations of 620 may be performed by a memory cell access component 435 as described with reference to FIG. 4.

In some examples, an apparatus as described herein may perform a method or methods, such as the method 500, the method 600, or both. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for applying, at a first time, a read voltage to a first set of memory blocks of a plurality of memory blocks, where the read voltage sets each memory block of the first set of memory blocks to a transient voltage state; applying, at a second time based at least in part on one or more reset conditions being satisfied, the read voltage to a second set of memory blocks of the plurality of memory blocks, where the read voltage sets each memory block of the second set of memory blocks to the transient voltage state; receiving an access command to access one or more memory cells within the first set of memory blocks, the second set of memory blocks, or both after applying the read voltage to the first set of memory blocks and the second set of memory blocks; and accessing the one or more memory cells based at least in part on the access command and the one or more memory cells being set to the transient voltage state.

Aspect 2: The method, apparatus, or non-transitory computer-readable medium of aspect 1, further including operations, features, circuitry, logic, means, or instructions, or any combination thereof for transitioning from a first power state to a second power state that is associated with greater power consumption than the first power state, where applying the read voltage to the first set of memory blocks is based at least in part on transitioning to the second power state.

Aspect 3: The method, apparatus, or non-transitory computer-readable medium of any of aspects 1 through 2, further including operations, features, circuitry, logic, means, or instructions, or any combination thereof for determining a time period between the first time and the second time satisfies a threshold duration, where applying the read voltage to the second set of memory blocks at the second time is based at least in part on the time period satisfying the threshold duration, and where the one or more reset conditions include the threshold duration.

Aspect 4: The method, apparatus, or non-transitory computer-readable medium of any of aspects 1 through 3, where the one or more reset conditions include a threshold duration associated with a voltage threshold state of the plurality of memory blocks, a temperature of the plurality of memory blocks, or any combination thereof.

Aspect 5: The method, apparatus, or non-transitory computer-readable medium of any of aspects 1 through 4, where the first set of memory blocks is within a first plane of a first memory die and the second set of memory blocks is within the first plane of a second memory die.

Aspect 6: The method, apparatus, or non-transitory computer-readable medium of aspect 5, further including operations, features, circuitry, logic, means, or instructions, or any combination thereof for applying, at a third time based at least in part on the one or more reset conditions being satisfied at the third time, the read voltage to a third set of memory blocks of the plurality of memory blocks, the third set of memory blocks within a second plane of the first memory die and applying, at a fourth time based at least in part on the one or more reset conditions being satisfied at the fourth time, the read voltage to a fourth set of memory blocks of the plurality of memory blocks, the fourth set of memory blocks within the second plane of the second memory die.

Aspect 7: The method, apparatus, or non-transitory computer-readable medium of any of aspects 1 through 6, where the read voltage is applied to the first set of memory blocks and the second set of memory blocks according to a reset sequence and the one or more reset conditions, the reset sequence associated with setting a threshold quantity of memory blocks of the plurality of memory blocks to the transient voltage state.

Aspect 8: The method, apparatus, or non-transitory computer-readable medium of aspect 7, where the reset sequence is associated with iteratively resetting all memory blocks in a plane of each memory die of a plurality of memory dies before transitioning to iteratively resetting all memory blocks in one or more other planes of each memory die of the plurality of memory dies.

Aspect 9: The method, apparatus, or non-transitory computer-readable medium of any of aspects 1 through 8, where prior to applying the read voltage, one or more memory blocks of the first set of memory blocks and the second set of memory blocks are set to a stable voltage state; the stable voltage state is associated with a first voltage distribution and the transient voltage state associated with a second voltage distribution; and the first voltage distribution is associated with a higher bit error rate than the second voltage distribution.

Aspect 10: A method, apparatus, or non-transitory computer-readable medium including operations, features, circuitry, logic, means, or instructions, or any combination thereof for applying, at a first time via a first GRR and based at least in part on one or more reset conditions being satisfied at the first time, a read voltage to a first set of memory blocks of a plurality of memory blocks, where the read voltage sets each memory block of the first set of memory blocks to a transient voltage state; applying, at a second time via a second GRR and based at least in part on the one or more reset conditions being satisfied at the second time, the read voltage to the first set of memory blocks, where the one or more reset conditions being satisfied at the second time is based at least in part on at least one memory block of the first set of memory blocks transitioning to a stable voltage state between the first time and the second time; receiving an access command to access one or more memory cells within the first set of memory blocks after applying the read voltage to the first set of memory blocks at the second time; and accessing the one or more memory cells based at least in part on the access command and the one or more memory cells being set to the transient voltage state.

Aspect 11: The method, apparatus, or non-transitory computer-readable medium of aspect 10, where a GRR is associated with applying the read voltage to a plurality of memory cells at a same time.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
apply, at a first time, a read voltage to a first set of memory blocks of a plurality of memory blocks, wherein the read voltage sets each memory block of the first set of memory blocks to a transient voltage state;
apply, at a second time based at least in part on one or more reset conditions being satisfied, the read voltage to a second set of memory blocks of the plurality of memory blocks, wherein the read voltage sets each memory block of the second set of memory blocks to the transient voltage state;
receive an access command to access one or more memory cells within the first set of memory blocks, the second set of memory blocks, or both after applying the read voltage to the first set of memory blocks and the second set of memory blocks; and
access the one or more memory cells based at least in part on the access command and the one or more memory cells being set to the transient voltage state.

2. The memory system of claim 1, wherein the processing circuitry is further configured to cause the memory system to:
transition from a first power state to a second power state that is associated with greater power consumption than the first power state, wherein applying the read voltage to the first set of memory blocks is based at least in part on transitioning to the second power state.

3. The memory system of claim 1, wherein the processing circuitry is further configured to cause the memory system to:
determine a time period between the first time and the second time satisfies a threshold duration, wherein applying the read voltage to the second set of memory blocks at the second time is based at least in part on the time period satisfying the threshold duration, and wherein the one or more reset conditions comprise the threshold duration.

4. The memory system of claim 1, wherein the one or more reset conditions comprise a threshold duration associated with a voltage threshold state of the plurality of memory blocks, a temperature of the plurality of memory blocks, or any combination thereof.

5. The memory system of claim 1, wherein the first set of memory blocks is within a first plane of a first memory die and the second set of memory blocks is within the first plane of a second memory die.

6. The memory system of claim 5, wherein the processing circuitry is further configured to cause the memory system to:
apply, at a third time based at least in part on the one or more reset conditions being satisfied at the third time, the read voltage to a third set of memory blocks of the plurality of memory blocks, the third set of memory blocks within a second plane of the first memory die; and
apply, at a fourth time based at least in part on the one or more reset conditions being satisfied at the fourth time, the read voltage to a fourth set of memory blocks of the plurality of memory blocks, the fourth set of memory blocks within the second plane of the second memory die.

7. The memory system of claim 1, wherein the read voltage is applied to the first set of memory blocks and the second set of memory blocks according to a reset sequence and the one or more reset conditions, the reset sequence associated with setting a threshold quantity of memory blocks of the plurality of memory blocks to the transient voltage state.

8. The memory system of claim 7, wherein the reset sequence is associated with iteratively resetting all memory blocks in a plane of each memory die of a plurality of memory dies before transitioning to iteratively resetting all memory blocks in one or more other planes of each memory die of the plurality of memory dies.

9. The memory system of claim 1, wherein:
prior to applying the read voltage, one or more memory blocks of the first set of memory blocks and the second set of memory blocks are set to a stable voltage state;
the stable voltage state is associated with a first voltage distribution and the transient voltage state associated with a second voltage distribution; and
the first voltage distribution is associated with a higher bit error rate than the second voltage distribution.

10. A method for a memory system, comprising:
applying, at a first time, a read voltage to a first set of memory blocks of a plurality of memory blocks, wherein the read voltage sets each memory block of the first set of memory blocks to a transient voltage state;
applying, at a second time based at least in part on one or more reset conditions being satisfied, the read voltage to a second set of memory blocks of the plurality of memory blocks, wherein the read voltage sets each memory block of the second set of memory blocks to the transient voltage state;
receiving an access command to access one or more memory cells within the first set of memory blocks, the second set of memory blocks, or both after applying the read voltage to the first set of memory blocks and the second set of memory blocks; and
accessing the one or more memory cells based at least in part on the access command and the one or more memory cells being set to the transient voltage state.

11. The method of claim 10, further comprising:
transitioning from a first power state to a second power state that is associated with greater power consumption than the first power state, wherein applying the read voltage to the first set of memory blocks is based at least in part on transitioning to the second power state.

12. The method of claim 10, further comprising:
determining a time period between the first time and the second time satisfies a threshold duration, wherein applying the read voltage to the second set of memory blocks at the second time is based at least in part on the time period satisfying the threshold duration, and wherein the one or more reset conditions comprise the threshold duration.

13. The method of claim 10, wherein the one or more reset conditions comprise a threshold duration associated with a voltage threshold state of the plurality of memory blocks, a temperature of the plurality of memory blocks, or any combination thereof.

14. The method of claim 10, wherein the first set of memory blocks is within a first plane of a first memory die and the second set of memory blocks is within the first plane of a second memory die.

15. The method of claim 14, further comprising:
applying, at a third time based at least in part on the one or more reset conditions being satisfied at the third time, the read voltage to a third set of memory blocks of the plurality of memory blocks, the third set of memory blocks within a second plane of the first memory die; and
applying, at a fourth time based at least in part on the one or more reset conditions being satisfied at the fourth time, the read voltage to a fourth set of memory blocks of the plurality of memory blocks, the fourth set of memory blocks within the second plane of the second memory die.

16. The method of claim 10, wherein the read voltage is applied to the first set of memory blocks and the second set of memory blocks according to a reset sequence and the one or more reset conditions, the reset sequence associated with setting a threshold quantity of memory blocks of the plurality of memory blocks to the transient voltage state.

17. The method of claim 16, wherein the reset sequence is associated with iteratively resetting all memory blocks in a plane of each memory die of a plurality of memory dies before transitioning to iteratively resetting all memory blocks in one or more other planes of each memory die of the plurality of memory dies.

18. The method of claim 10, wherein:
prior to applying the read voltage, one or more memory blocks of the first set of memory blocks and the second set of memory blocks are set to a stable voltage state;
the stable voltage state is associated with a first voltage distribution and the transient voltage state associated with a second voltage distribution; and
the first voltage distribution is associated with a higher bit error rate than the second voltage distribution.

19. A non-transitory computer-readable medium storing code for a memory system, the code comprising instructions executable by one or more processors to:
apply, at a first time, a read voltage to a first set of memory blocks of a plurality of memory blocks, wherein the read voltage sets each memory block of the first set of memory blocks to a transient voltage state;
apply, at a second time based at least in part on one or more reset conditions being satisfied, the read voltage to a second set of memory blocks of the plurality of memory blocks, wherein the read voltage sets each memory block of the second set of memory blocks to the transient voltage state;
receive an access command to access one or more memory cells within the first set of memory blocks, the second set of memory blocks, or both after applying the read voltage to the first set of memory blocks and the second set of memory blocks; and
access the one or more memory cells based at least in part on the access command and the one or more memory cells being set to the transient voltage state.

20. The non-transitory computer-readable medium of claim 19, wherein the instructions are further executable by the one or more processors to:
transition from a first power state to a second power state that is associated with greater power consumption than the first power state, wherein applying the read voltage to the first set of memory blocks is based at least in part on transitioning to the second power state.

21. The non-transitory computer-readable medium of claim 19, wherein the instructions are further executable by the one or more processors to:
determine a time period between the first time and the second time satisfies a threshold duration, wherein applying the read voltage to the second set of memory blocks at the second time is based at least in part on the time period satisfying the threshold duration, and wherein the one or more reset conditions comprise the threshold duration.

22. The non-transitory computer-readable medium of claim 19, wherein the one or more reset conditions comprise a threshold duration associated with a voltage threshold state of the plurality of memory blocks, a temperature of the plurality of memory blocks, or any combination thereof.

23. The non-transitory computer-readable medium of claim 19, wherein the first set of memory blocks is within a first plane of a first memory die and the second set of memory blocks is within the first plane of a second memory die.

24. The non-transitory computer-readable medium of claim 23, wherein the instructions are further executable by the one or more processors to:
apply, at a third time based at least in part on the one or more reset conditions being satisfied at the third time, the read voltage to a third set of memory blocks of the plurality of memory blocks, the third set of memory blocks within a second plane of the first memory die; and
apply, at a fourth time based at least in part on the one or more reset conditions being satisfied at the fourth time, the read voltage to a fourth set of memory blocks of the plurality of memory blocks, the fourth set of memory blocks within the second plane of the second memory die.

25. The non-transitory computer-readable medium of claim 19, wherein the read voltage is applied to the first set of memory blocks and the second set of memory blocks according to a reset sequence and the one or more reset conditions, the reset sequence associated with setting a threshold quantity of memory blocks of the plurality of memory blocks to the transient voltage state.

26. A memory system, comprising:
one or more memory devices; and
processing circuitry coupled with the one or more memory devices and configured to cause the memory system to:
apply, at a first time via a first ganged reset read (GRR) and based at least in part on one or more reset conditions being satisfied at the first time, a read voltage to a first set of memory blocks of a plurality of memory blocks, wherein the read voltage sets each memory block of the first set of memory blocks to a transient voltage state;
apply, at a second time via a second GRR and based at least in part on the one or more reset conditions being satisfied at the second time, the read voltage to the first set of memory blocks, wherein the one or more reset conditions being satisfied at the second time is based at least in part on at least one memory block of the first set of memory blocks transitioning to a stable voltage state between the first time and the second time;
receive an access command to access one or more memory cells within the first set of memory blocks after applying the read voltage to the first set of memory blocks at the second time; and
access the one or more memory cells based at least in part on the access command and the one or more memory cells being set to the transient voltage state.

27. The memory system of claim 26, wherein the first GRR and the second GRR are associated with applying the read voltage to a plurality of memory cells at a same time.

28. The memory system of claim 26, wherein the stable voltage state is associated with a first voltage distribution and the transient voltage state associated with a second voltage distribution, and wherein the first voltage distribution is associated with a higher bit error rate than the second voltage distribution.

29. A method for a memory system, comprising:
applying, at a first time via a first ganged reset read (GRR) and based at least in part on one or more reset conditions being satisfied at the first time, a read voltage to a first set of memory blocks of a plurality of memory blocks, wherein the read voltage sets each memory block of the first set of memory blocks to a transient voltage state;
applying, at a second time via a second GRR and based at least in part on the one or more reset conditions being satisfied at the second time, the read voltage to the first set of memory blocks, wherein the one or more reset conditions being satisfied at the second time is based at least in part on at least one memory block of the first set of memory blocks transitioning to a stable voltage state between the first time and the second time;
receiving an access command to access one or more memory cells within the first set of memory blocks after applying the read voltage to the first set of memory blocks at the second time; and
accessing the one or more memory cells based at least in part on the access command and the one or more memory cells being set to the transient voltage state.

30. The method of claim 29, wherein the first GRR and the second GRR are associated with applying the read voltage to a plurality of memory cells at a same time.
